(19) United States
(12) Patent Application Publication
(10) Pub. No.: US 2012/0267982 A1
(43) Pub. Date: Oct. 25, 2012

(54) NON-CONTACT MECHANICAL ENERGY HARVESTING DEVICE AND METHOD UTILIZING FREQUENCY RECTIFICATION

(75) Inventors: Gregory P. Carman, Los Angeles, CA (US); Dong Gun Lee, Los Angeles, CA (US)

(73) Assignee: The Regents of the University of California, Oakland, CA (US)

(21) Appl. No.: 12/518,613

(22) PCT Filed: Dec. 21, 2007
(86) PCT No.: PCT/US07/26123

§ 371 Date: Apr. 1, 2010

Related U.S. Application Data
(60) Provisional application No. 60/876,526, filed on Dec. 22, 2006.
(60) Provisional application No. 60/881,152, filed on Jan. 19, 2007.

(51) Int. Cl. H01L 41/113

(52) U.S. Cl. 310/318

(57) ABSTRACT

An energy harvesting apparatus includes an inverse frequency rectifier structured to receive mechanical energy at a first frequency, and a solid state electromechanical transducer coupled to the inverse frequency rectifier to receive a force provided by the inverse frequency rectifier. The force, when provided by the inverse frequency rectifier, causes the solid state transducer to be subjected to a second frequency that is higher than the first frequency to thereby generate electrical power. The coupling of the solid state electromechanical transducer to the inverse frequency rectifier is a non-contact coupling.

### CROSS-REFERENCE TO RELATED APPLICATION

This application claims priority to U.S. Provisional Application No. 60/876,526 filed Dec. 22, 2006 and to U.S. Provisional Application No. 60/881,152 filed Jan. 19, 2006, the entire contents of which are hereby incorporated by reference.

### BACKGROUND

1. Field of Invention

The present invention relates to energy harvesting, and more particularly to non-contact mechanical energy harvesting utilizing frequency rectification.

2. Discussion of Related Art

Energy harvesting (or energy scavenging) is defined as the conversion of ambient mechanical energy, for example, but not limited to, vibrational energy, into usable electrical energy. The electrical energy harvested can then be used as a power source for a variety of low-power applications, such as, but not limited to, remote applications that may involve networked systems of wireless sensors and/or communication nodes, where other power sources such as batteries may be impractical [J. A. Paradiso, T. Starner, IEEE Pervasive Computing, January-March:18-27 (2005); S. Roundy, E. S. Leland, J. Baker, E. Carleton, E. Reilly, E. Lai, B. Otis, J. M. Rabacy, P. K. Wright, IEEE Pervasive Computing, January-March:28-35 (2005)]. For these reasons, the amount of research devoted to power harvesting has been rapidly increasing [H. A. Sodano, D. J. Inman, G. Park, The Shook and Vibration Digest, Vol. 36: 197-205 (2004)].

[Vibration-based energy harvesters have been successfully developed using, for example, electromagnetic, electrostatic, and piezoelectric methods of electromechanical generation [S. Roundy, E. S. Leland, J. Baker, E. Carleton, E. Reilly, E. Lai, B. Otis, J. M. Rabacy, P. K. Wright, IEEE Pervasive Computing, January-March: 28-35 (2005)]. A piezoelectric harvester has gained considerable attention because piezoelectric energy conversion produces relatively higher voltage than other electromechanical generators. A piezoelectric harvester can convert mechanical energy into electrical energy by straining a piezoelectric material that then uses atomic deformations to change the polarization of the material and to produce net voltage changes. The net voltage can be scavenged and converted into stored power in either a battery or a capacitor, or it may be used as it is being created.

The amount of power accumulated via the piezoelectric harvester (or generator) is proportional to the mechanical frequency which is exciting it [H. W. Kim, A. Batra, S. Priya, K. Uchino, D. Markley, R. E. Newnham, H. F. Hofmann, The Japan Society of Applied Physics, Vol. 43 9A:6178-6183 (2004)]. In most non-resonant energy generators, the mechanical frequency input to the generator (e.g., piezoelectric material) corresponds to the environment's dominant mechanical frequency, which in most all cases is relatively low (i.e., below 100 Hz). For example, a heel-strike power harvester [N. S. Shenck, J. A. Paradiso, IEEE Micro, Vol. 21:30-41 (2001)], disclosed in U.S. Pat. No. 6,433,465 B1 (Mcknight et al.), harvests energy from a walking motion that occurs at approximately 1 Hz. The frequency of this generator matches the driving frequency of the heel strike. This low frequency generator limits the amount of electromechanical power that can be converted in a give volume. As a result, the power harvested via the non-resonant generator is insufficient to power most electronic-based systems. Therefore, a relatively small non-resonant generator may, typically, not be able to generate sufficient power due to the low-frequency ambient vibrations.

On the other hand, a resonant piezoelectric generator is disclosed in U.S. Pat. No. 3,456,134 (Ko et al.), U.S. Pat. No. 4,900,970 (Ando et al.) and U.S. Pat. No. 6,858,870 B2 (Malkin et al.). For the resonant vibration-based generators, the harvesting power can be maximized when the resonance frequency matches the driving frequency of the ambient vibration source [J. A. Paradiso, T. Starner, IEEE Pervasive Computing, January-March:18-27 (2005)]. Otherwise, the harvesting power output drops off dramatically as resonance frequency deviates from the driving frequency. To harvest maximum energy, the piezoelectric generator in such systems is designed to exploit the oscillation of a proof mass resonantly tuned to the environment's dominant mechanical frequency [S. Roundy, E. S. Leland, J. Baker, E. Carleton, E. Reilly, E. Laf, B. Otis, J. M. Rabacy, P. K. Wright, IEEE Pervasive Computing, January-March:28-35 (2005)]. The resonance frequency based harvesting approach limits operation to a very narrow frequency band and does not utilize the higher frequencies available from piezoelectric materials.

Conventional mechanical energy harvesting devices for micro-system use can be categorized into four different vibration-based mechanisms, as follows:

1. Piezoelectric based systems in which input vibrations are converted one-to-one for output power. These are based on the piezoelectric cantilever beam and proof mass arrangement such as illustrated in FIG. 1 [Y. B. Jeon, R. Sood, J. H. Jeong and S. G. Kim, Sensors and Actuators A: Physical, Vol. 122:16-22 (2005)].

2. Electrostatic based systems in which input vibrations are converted one-to-one for output power. These are based on the change of capacitance in the gap caused by relative motion of structures such as illustrated in FIG. 2 [S. Roundy, P. K. Wright, and J. Rabaey, Computer Communications, Vol. 26:1131-1144 (2003)].

3. Electro-magnetic based systems in which input vibrations are converted one-to-one for output power. These are based on magnet and coil arrangements such as illustrated in FIG. 3 [S. P. Beeby, M. J. Tudor, E. Koukhanenko, N. M. White, T. O'Donnell, C. Saha, S. Kulkarni, S. Roy, Transducers'05: 780-783 (2005)].

4. Acoustic based systems in which input acoustic waves are converted one-to-one for output power. These are based on the acoustic wave and related mechanical structure such as illustrated in FIG. 4 [S. B. Horowitz, M. Sheplak, L. N. Cattafesta III and T. Nishida, J. Micromech. Microeng. Vol. 16: S174-S181 (2006)].

Because most structural resonance frequencies are small (i.e., below 100 Hz), the amount of power that can be harvested per unit volume per device is limited because power is proportional to input frequency. It is therefore desirable to convert a low-range mechanical frequency to a higher resonant frequency, given that many conversion based systems such as piezoelectric materials and magnetostrictive materials are capable of operating at frequencies in the 10's of kHz. Harvesting power at these elevated frequencies represent orders of magnitude increases in power harvested per unit volume of device. In addition, mechanical energy harvesting devices that have moving parts that come in contact with each other result in decreased useful lifetimes and reliability problems. Therefore, there exists a need for improved mechanical energy harvesting devices and methods.

### SUMMARY

An energy harvesting apparatus according to an embodiment of the invention includes an inverse frequency rectifier structured to receive mechanical energy at a first frequency, and a solid state electromechanical transducer coupled to the inverse frequency rectifier to receive a force provided by the inverse frequency rectifier. The force, when provided by the inverse frequency rectifier, causes the solid state transducer to be subjected to a second frequency that is higher than the first frequency to thereby generate electrical power. The coupling of the solid state electromechanical transducer to the inverse frequency rectifier is via non-contact coupling. A system according to embodiments of the invention may comprise the above-described apparatus, as well as an electrical device coupled to receive the electrical signal. Embodiments of the invention may also include methods of implementing the above-described apparatus. Embodiments of the current invention may also include methods of manufacturing apparatuses according to the current invention.

The rectified frequency may be applied to an electro-mechanical or magneto-mechanical material to convert the mechanical power into electrical power. By using an electro-mechanical material a voltage-based harvesting system may be obtained, while by using a magneto-mechanical material a current-based harvesting system may be obtained.

### BRIEF DESCRIPTION OF THE DRAWINGS

Additional features of this invention are provided in the following detailed description of various embodiments of the invention with reference to the drawings. Furthermore, the above-discussed and other attendant advantages of the present invention will become better understood by reference to the detailed description when taken in conjunction with the accompanying drawings, in which:

FIG. 1 is a schematic illustration of a conventional piezoelectric energy harvesting device;

FIG. 2 is a schematic illustration of a conventional electrostatic energy harvesting device and a photograph of such a device;

FIG. 3 is a schematic illustration of a conventional electro-magnetic energy harvesting device and a photograph of such a device;

FIG. 4 is a schematic illustration of a conventional acoustic energy harvesting device;

FIG. 5 depicts a conventional resonant piezoelectric harvester operating schematic;

FIG. 6 depicts one embodiment of an inverse frequency rectification operating schematic with a mechanical rectifier;

FIG. 7 depicts a second embodiment of inverse frequency rectification with an array of frequency rectifiers;

FIG. 8 illustrates amplitude-time characteristics of an ambient vibration source;

FIG. 9 illustrates amplitude-time characteristics of the prior art in which no rectifier is used, for example, as shown in FIG. 5;

FIG. 10 illustrates amplitude-time characteristics of an embodiment of the invention in which one rectifier is used, for example, as with the embodiment shown in FIG. 6;

FIG. 11 illustrates amplitude-time characteristics of an embodiment of the invention in which three series of rectifiers are used, for examples, as with the embodiment shown in FIG. 7;

FIG. 12 illustrates a general system block diagram according to embodiments of the invention;

FIG. 13 is a schematic illustration of a portion of a non-contact energy harvesting device according to an embodiment of the current invention;

FIG. 14 is a schematic illustration of a method of manufacturing a portion of a non-contact energy harvesting device according to the current invention;

FIG. 15 helps illustrate some concepts of non-contact energy harvesting devices according to an embodiment of the current invention;

FIG. 16 helps illustrate some concepts of non-contact energy harvesting devices according to another embodiment of the current invention;

FIGS. 17A-17C illustrate another breadboard system according to an embodiment of the current invention that is useful to help explain some general concepts;

FIG. 18 is a schematic illustration of an energy harvesting apparatus according to an embodiment of the current invention;

FIG. 19 is a schematic illustration describing the manufacture of an energy harvesting apparatus according to an embodiment of the current invention;

FIG. 20 is a photograph of an energy harvesting apparatus according to an embodiment of the current invention; and

FIG. 21 shows the output from the energy harvesting apparatus of FIG. 20.

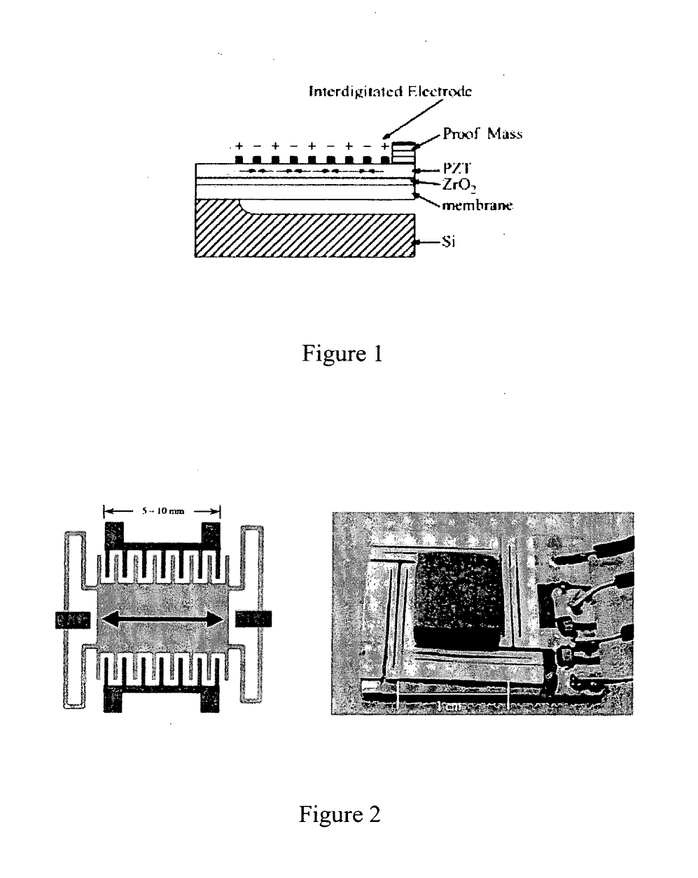

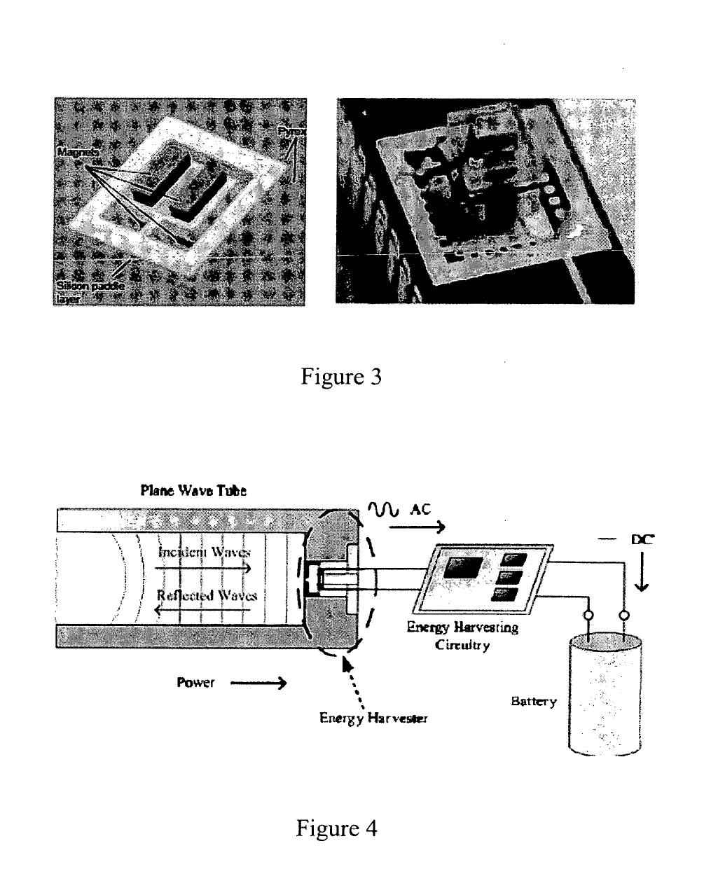

### DETAILED DESCRIPTION OF VARIOUS EMBODIMENTS

The present invention represents a significant advancement compared to prior energy harvesting designs. An inverse frequency rectification device and method according to embodiments of the current invention converts a low frequency oscillation source, which may, for example, be from an ambient vibration, to a much higher frequency oscillation. This rectification allows substantially more power per unit mass to be harvested than previously possible. To date all the energy harvesters have relied on the relatively low ambient vibrations and have not used inverse frequency rectification. The addition of frequency rectifiers can dramatically increase the power output per unit volume. The inverse frequency rectification approach can potentially generate power densities on the order of W/cm³ levels, two to three orders of magnitude larger than currently obtainable by conventional piezoelectric energy harvesters.

Inverse frequency rectification may be provided in accordance with embodiments of the present invention to generate higher resonant frequency vibration without changing the generator design for resonance-tuning. Given this, it may be advantageous to have a single design that operates effectively over a range of vibration frequencies. The following detailed description sets forth examples of embodiments of the current invention to facilitate an explanation of concepts of this invention. The current invention is not limited to the specific embodiments described in detail.

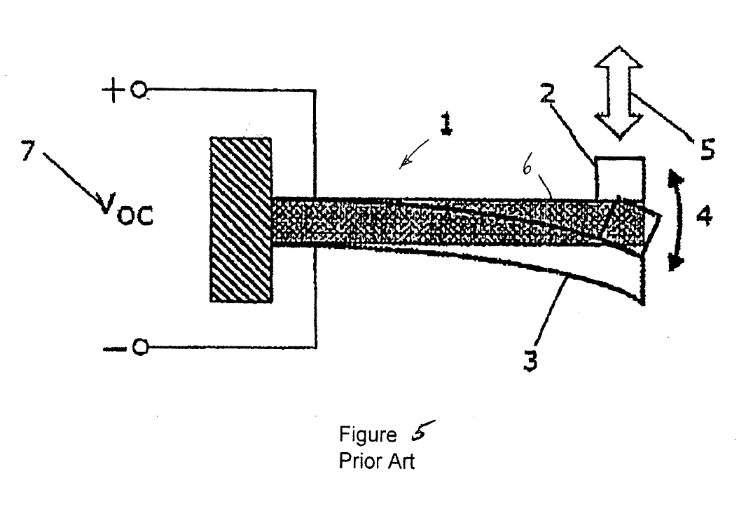

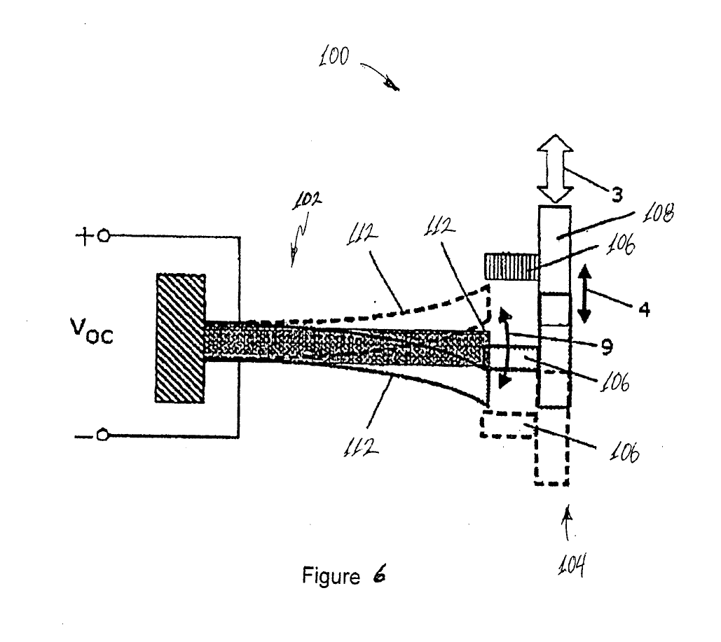

FIG. 5 shows an embodiment of a conventional piezoelectric generator. In FIG. 5, a resonant piezoelectric generator comprises a piezoelectric material generator 1 in the form of a clamped cantilever beam 6. A proof mass 2 is attached to the free end of the beam 6. The beam is excited by transverse vibrations. An ambient vibration source 5 causes the cantilever beam 6 to resonate at the frequency corresponding to the environment's dominant mechanical frequency. As the figure shows, bending the beam 6 downward or upward during resonance mode 3 produces a repeated mechanical strain. By inducing a strain in a piezoelectric material, a voltage 7 is generated across the beam, and energy may be harvested from the system, for example, using electrical contacts (e.g., wire leads) coupled to the piezoelectric material. The amplitude of deformation is determined by the geometry, mass at the tip and material of the generator.

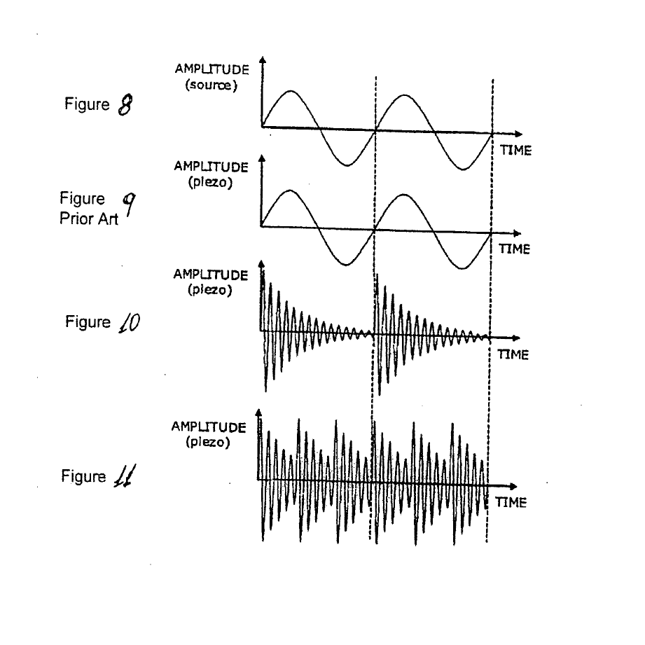

FIG. 8 shows the displacement amplitude waveform associated with the harmonic ambient driving force during two cycles. FIG. 9 shows the excited piezoelectric generator's displacement (or, equivalently, voltage) amplitude waveform. The generator resonates with small amplitude at the frequency corresponding to the driving frequency shown in FIG. 8.

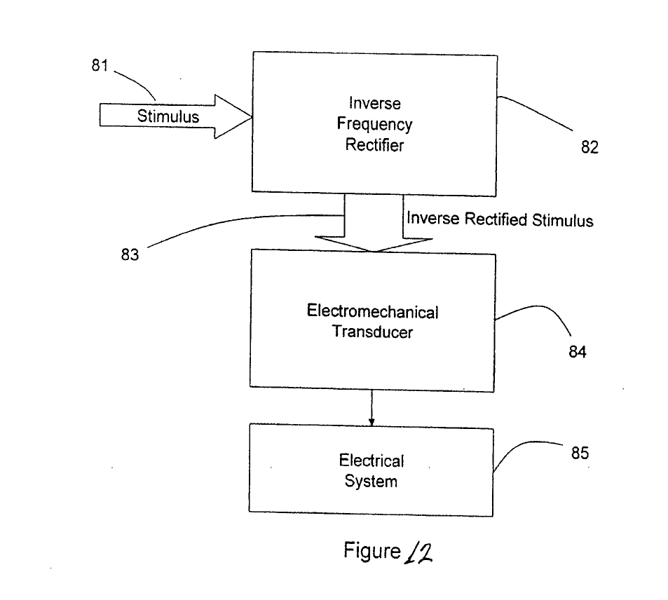

FIG. 6 illustrates an embodiment of an inverse frequency rectification device in accordance with the invention. “Frequency rectification” refers to the conversion of high frequency oscillation/movement to low frequency oscillation/movement; hence, “inverse frequency rectification” refers to the conversion of low frequency oscillation/movement to high frequency oscillation/movement. One operating mode of the invention may be in the form of a piezoelectric cantilever-based system as in the aforementioned conventional vibration-based harvester. While a cantilever is depicted in the figure this component could be a plate or a compression member. The proposed inverse frequency rectification device 100 may be comprised of at least one energy generator 102 exhibiting strain induced electrical energy and a frequency rectifier 104 made of a rubber rectifier 106 attached to a metal bar 108. The general concepts of the invention are not limited to the particular materials and structures described in the current example. The rectifier 106 bends the beam 112 downward. The beam 112 released from rectifier 106 vibrates at the natural frequency of beam 112 with varying amplitude. The excited frequency is in practice typically much higher than that of the conventional generator shown in FIG. 5. FIG. 10 shows an example of a voltage amplitude waveform of the piezoelectric generator with a single rectifier, as shown in FIG. 6.

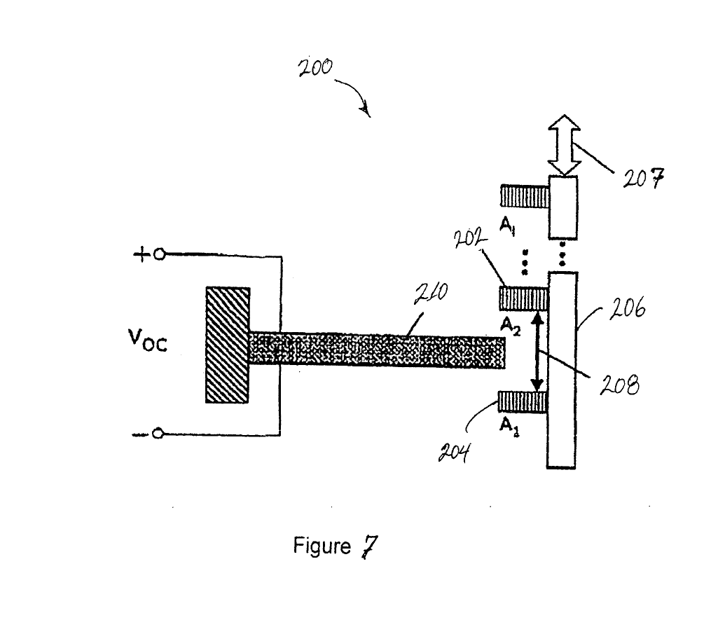

FIG. 7 illustrates an embodiment of an inverse frequency rectification device 200 with multiple rectifiers 202 and 204 attached to metal bar 206. The invention is not limited to the use of only metal bars 206 for the inverse frequency rectification device 200. Other materials (including nonlinear exotic materials such as pseudoelastic NiTi) and structures may be used without departing from the scope of the invention. As in FIG. 6, as the rectifiers 202 and 204 are moved in accordance with the resonance mode 207, each time a distance 208 between rectifiers 202 and 204 is traversed (in either direction), energy generator 210 is bent and released, resulting in the reinitiation of vibration of energy generator 210 each time it is bent and released by a rectifiers 202 and 204. As a result, improved power output per unit volume may be obtained. FIG. 11 shows an example of voltage amplitude waveform of the piezoelectric generator with multiple rectifiers, for example, three rectifiers in this case. Note that the number of such rectifiers 202, 204 is arbitrary, and the resulting voltage amplitude waveform may have a shape that correlates with the number of rectifiers 202, 204 (e.g., in terms of the number of excitation peaks). An inverse frequency rectifier may have one, two, three or a larger number of rectifiers, including a continuous non-discrete system, without departing from the scope of this invention.

As discussed above, the above embodiments are shown in the figures using an inverse frequency rectification scheme in which a bar or other surface having transversely mounted tooth-like rectifiers is vibrated such that the rectifiers cause a flexible, displaceable structure to repeatedly be excited into vibration. However, the invention is not intended to be limited to such embodiments. Rather the invention is intended to encompass any inverse frequency rectification method or device in accordance with the general concepts of this invention, including circular, linear, or otherwise approaches. For example, an alternative structure may use gears to achieve inverse frequency rectification in a circular fashion. Another alternative structure may utilize a rack-and-pinion-based system to achieve a continuous non-discrete system.

FIG. 12 illustrates a general block diagram of a system according to embodiments of the invention. In general, a mechanical stimulus 81 at a first frequency may be applied to an inverse frequency rectifier 82. In general, there may be multiple frequencies and/or a band of frequencies that excite the inverse frequency rectifier 82. The inverse frequency rectifier 82 outputs an inverse rectified stimulus 83 at a second frequency that excites an electromechanical transducer at a higher frequency than the first frequency. One should understand that the second frequency may be one of a spectrum of frequencies. The inverse rectified stimulus 83 may then be applied to an electromechanical transducer 84, which may be, for example (but is not limited to), a piezoelectric-based device (which could be utilize 3-3 or 3-1 modes as well as more complicated crystal structures), as discussed above, to convert the inverse rectified mechanical stimulus 83 to electrical energy. The electrical energy thus produced may be applied to an electrical system 85. As discussed above, electrical system 85 may include one or more storage devices (batteries, capacitors, etc.) and/or circuits to which the electrical energy may be directly applied.

A system like that of FIG. 12 may be deployed in many scenarios. Typical scenarios are those in which a low-power electrical system is to be powered in an environment where there is ambient mechanical stimulus (e.g., vibration). (Typical ambient mechanical frequencies that may excite an inverse frequency rectifier may be, for example about 0.1 Hz to 1,000 Hz while suitable solid state components may be selected from available electromechanical transducers that oscillate at about 100 Hz to about 1 GHz. However, these are just some examples. The general concepts of this invention are not limited to these particular parameters.) For example, remote sensing and/or communication devices may be deployed in such environments (e.g., mounted on machinery or other platforms that normally vibrate, are subjected to vibration, and/or otherwise move), and embodiments of the inventive system may be used to provide power to such devices without the use of batteries or wired power sources.

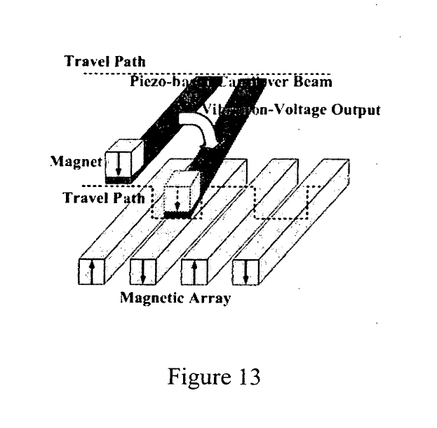

FIG. 13 is a schematic illustration of a non-contact frequency rectification device according to an embodiment of the current invention. This is an embodiment of a linear system utilizing magnetic forces to rectify the frequency of the incoming mechanical vibration. The current invention is not limited to only such linear systems. For example, other systems such as rotational, 3-D approaches, or rack/pinion systems are within the scope of the current invention as well as other non-contact transmissions, e.g. Coulomb forces or Van der Waals forces. In particular, FIG. 13 illustrates a non-contact vibration-based magnetic energy harvesting device. The device comprises two major parts: one is a non-contact transmission component, in this case a magnetic array which is on a substrate in FIG. 13, and another is the solid state electromechanical converter (i.e. cantilever beam in FIG. 13) that has a single magnet attached to it. When the cantilever beam translates through the variable magnetic field setup by the magnetic array, the cantilever beam will experience alternative repulsive and attractive magnetic forces generated from the magnetic array. While FIG. 13 shows alternating repulsive and attractive forces on the substrate, one can also imagine that these could be patterned into any array so that the magnetic force varies with position (e.g. they could all be poled in a similar direction and the magnet attached to the cantilever beam could be composed of multiple magnets). There is a multitude of variations based on this concept, all of which are intended to be within the scope of the current invention. In addition to different magnetic materials and patterns, the energy transmission need not be a beam but could take on a wide range of geometries including but not limited to a plate, a membrane, a curved structure, or a direct drive mechanism. When the cantilever beam in FIG. 13 experiences alternating magnetic forces, the cantilever beam produces a time-varying deflection as a function of the translational speed of the magnetic array. As the magnetic array is moved one translation cycle in a unit time, the cantilever beam experiences a number of oscillations functionally dependent upon the number, arrangement, and geometry of magnets that are present in the array. The magnetic arrangement directly correlates with the rectified frequency. For a 1 hertz input into the magnetic array, and assuming 5 magnets on the array, the frequency is up-converted to a 5 hertz excitation of the beam. Since the beam is a solid state electromechanical converter, in this embodiment a piezoelectric device, the mechanical energy produces an electrical charge on the surface which can be harvested as electrical energy. Other solid state electromechancial converters exist that can replace the piezoelectric beam, such as magnetostrictive, ferroelectric, or ferromagnetic materials, without departing from the general concepts of this invention. Also other modes of transmission outside of 3-1, 33, and 1-5 are possible as well as other geometries of the electromechanical converter.

The following is an example of fabricating methods for a developing a non-contact frequency rectification system. Two main structural components of such an embodiment, i.e., (1) a non-contact array (e.g. NdFeB Magnetic Array) and (2) a solid state electro-mechanical converter, maybe fabricated according to an embodiment of the current invention as described below. However, methods of manufacture according to the current invention are not limited to this example and include scales from nano to macro (cm). After fabrication, the components (1) & (2) may be assembled using various related techniques including MEMS (deposit sacrificial layer, deposit binding film, etch to specific pattern) or alternatively the entire system may be fabricated simultaneously on a single wafer. Below we describe the fabrication details of an example that has a NdFeB magnetic array and a piezoelectric electromechanical energy converter. The current invention is not limited to only this example. The example focuses on the manufacturing process to create the magnetic array. This is the primary focus because the spacing of the magnets will typically translate in the degree of rectification. Also while the description is in terms of NdFeB, other magnetic materials could also be used as well as other fabrication procedures.

(1) NdFeB Magnetic Array Fabrication Process
Macro-Scale Fabrication Process

For a macroscopic system the Nd—Fe—B is melt spun onto a surface. Following the deposition of the Nd—Fe—B onto the surface, the Nd—Fe—B is mechanically machined into isolated regions. A representative dimension between magnets can be down to 100 microns in spacing. Once the system is geometrically in place, the Nd—Fe—B system is magnetized with a strong magnetic field at elevated temperature.
Micro-Scale Fabrication Process

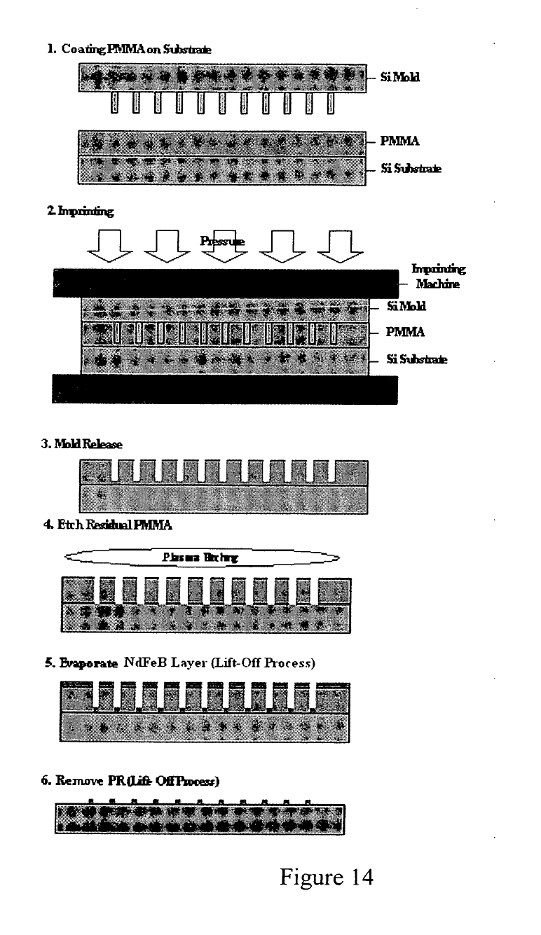

For microscale fabrication the NdFeB is typically sputter deposited onto a silicon wafer. Once deposited, a photoresist is spin coated on the surface and patterned into the desired dimensions. A typically dimension can be down to 1 micron in spacing. Following the patterning of the photoresist, the NdFeB is etched with a Salpetric Acid solution to form the structure of the magnetic rectificater. Following fabrication the system is magnetically poled at an elevated temperature.
Nano-Scale Fabrication Process (Shown as FIG. 14)

For nanoscale fabrication a nano-imprinting lithographic approach is used. Nanoimprint lithography creates a resist relief pattern by deforming the resist physical shape with embossing. Nanoimprint lithography can produce sub-10 nm features over a large area with low cost. In the imprinting process, a mold with nanostructures on its surface is pressed into a thin resist cast on a substrate. The resist, a thermal plastic, for example, but not limited to polymethylmethacrylate (PMMA), is deformed readily by the mold when heated above its glass transition temperature. After the resist is cooled below its glass transition temperature, the mold is removed. Following the mold removal, an anisotropic etching process such as reactive ion etching is used to remove the residual resist in the compressed area. Following the imprinting process, the NdFeB system is sputter deposited onto the surface as shown in FIG. 14. Following the deposition the system is lifted off. It should be noted that in the nanoscale it maybe possible to use a layered ferromagnetic system to allow exchange coupling interaction between the ferromagnetic layers and improve the properties of the material as compared to the macro or microscopic system described above. Following the lift off process, the system is poled in a strong magnetic field at elevated temperatures.

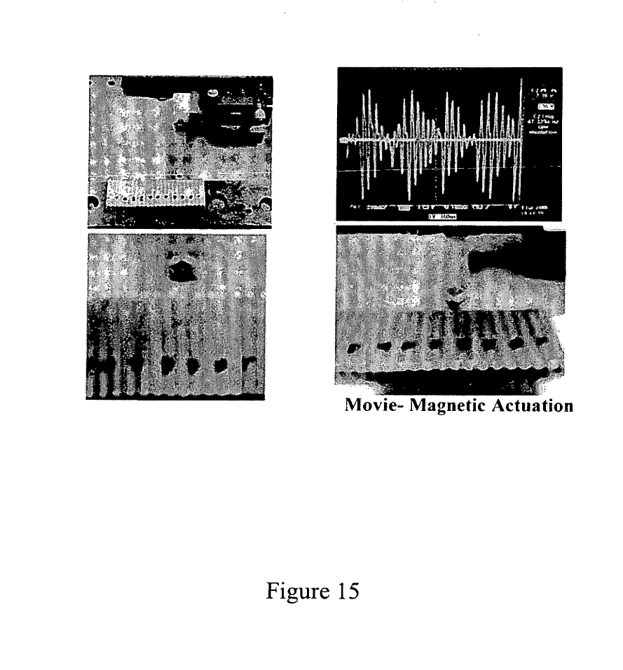

FIG. 15 illustrates a breadboard system according to the current invention that is useful to help illustrate some general concepts. The breadboard system in this example has a magnetic pad array that has 3 mm thick Nd—Fe—B magnets attached to a thin Ni—Cu—Ni plate. In addition to these magnets, a a 3 mm NdFeB magnet is placed on the piezoelectric bimorph cantilever beam. As the system experiences vibrations, the plate translates beneath the piezoelectric beam. The alternating magnetic field produces forces on the piezoelectric beam that up converts the frequency from the incoming vibration to a value defined by the amplitude and the number of magnetics attached to the plate. The trace of the oscilloscope show the voltage output from the piezoelectric and the rectification of the incoming signal.

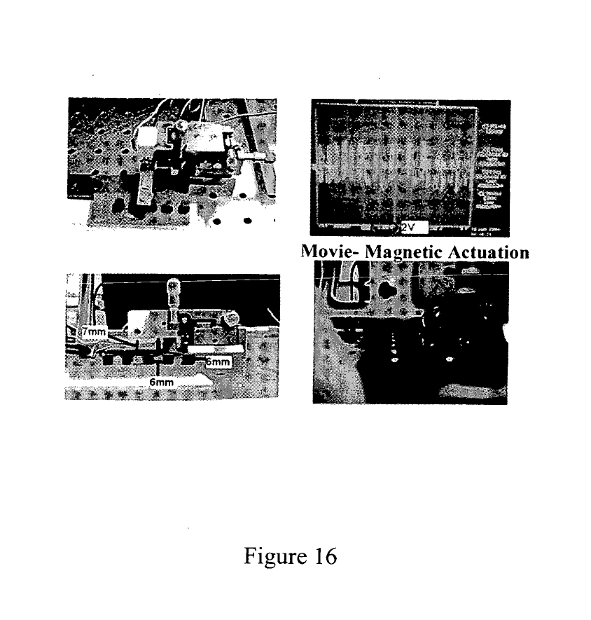

FIG. 16 illustrates another breadboard system according to the current invention that is useful to help illustrate some general concepts. In particular, a piezoelectric bimorph with a NdFeB magnetic is physically moved with a micrometer on the top surfaces of a magnetic array. The 3 mm NdFeB magnetic array is constructed on a Ni—Cu—Ni plate. As the piezoelectric bimorph moves, the magnetic forces produce a bending motion that creates a voltage on the piezoelectric surface. This voltage is presented in the oscilloscope trace shown in the figure. The purpose of this illustration is to show that for each linear motion, the voltage is oscillated five times in accordance with the number of magnets on the plate. This provides a non-contact and non-wear approach to transfer the forces.

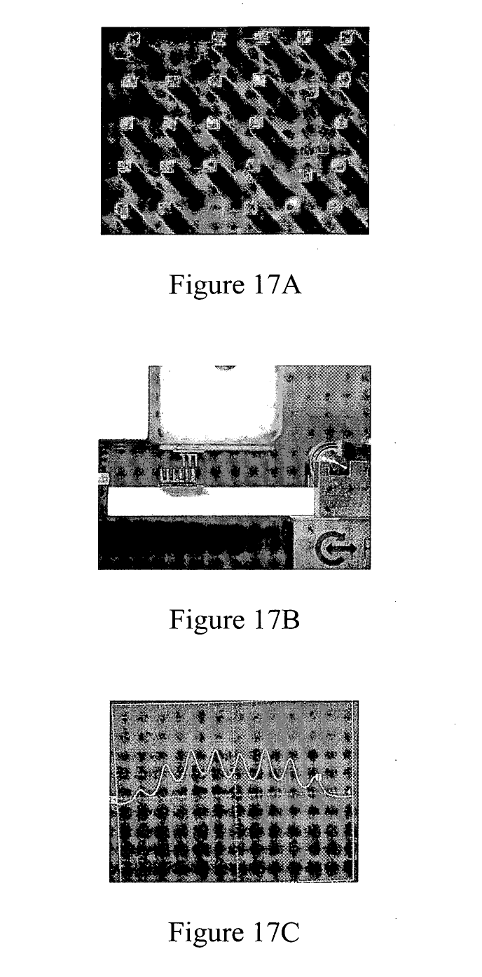

The breadboard system in the example illustrated in FIGS. 17A-17C has a micro fabricated magnet array. The magnet array has 100 micron thick Nd—Fe—B magnets (see FIG. 17A) that are attached to a silicon substrate. In addition to these micro magnet arrays as a bottom layer, a 100 micron thick NdFeB magnet array is attached to a piezoelectric bimorph cantilever beam for a top layer. The silicon substrate with the micro magnet array is placed on a vibration shaker that is shown in FIG. 17B. The trace of the oscilloscope shows the voltage output from the piezoelectric and the rectification of the incoming signal.

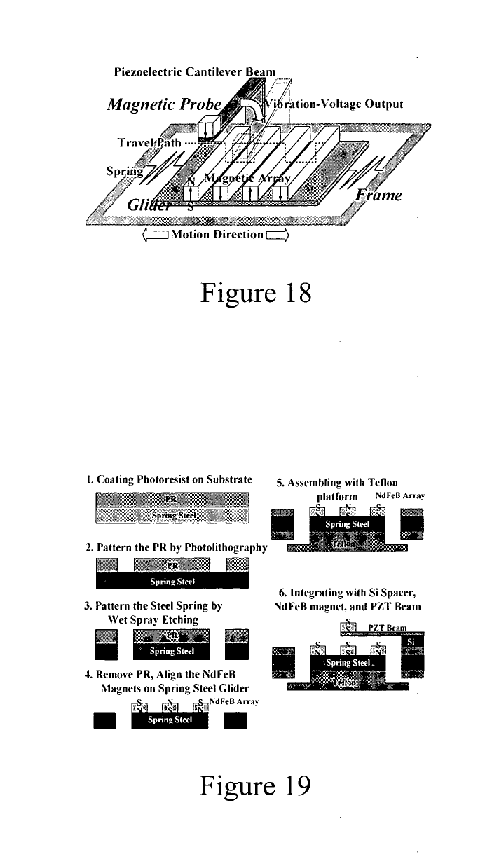

FIG. 18 is a schematic illustration of an energy harvesting apparatus according to an embodiment of the current invention. The energy harvesting apparatus in this embodiment includes three main parts: a magnetic probe, a glider, and a frame. The magnetic probe is a piezoelectric cantilever beam with an NdFeB magnet attached to the end of the beam. The glider is a steel plate with an array of NdFeB magnets on its surface and connected to the frame by springs. When the device experiences a mechanical vibration from the environment, the glider moves in the horizontal direction while the piezoelectric cantilever beam remains fixed in the horizontal plane. As the NdFeB magnets on the glider translate beneath the piezoelectric beam, the piezoelectric beam experiences alternative repulsive and attractive magnetic forces generated from the NdFeB magnets array. These magnetic forces cause the piezoelectric cantilever beam to deflect accordingly. For one cycle, the frequency is increased proportional to the number of magnets on the glider, i.e. frequency rectification. This occurs through a non-contact approach.

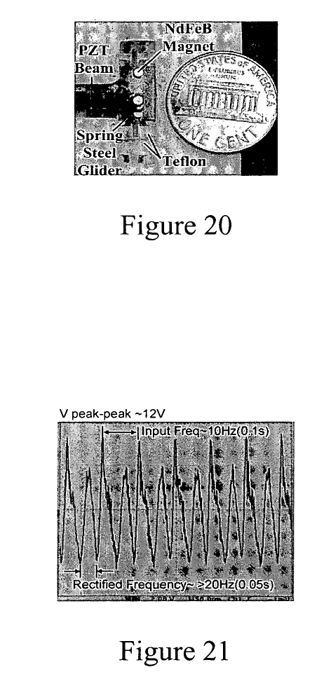

A fabrication process for the energy harvesting apparatus in the embodiment of FIG. 18 is illustrated schematically in FIG. 19. A layer of photoresist is spin coated onto spring steel. The photoresist layer is patterned using photolithography and then the spring steel is patterned by wet spray etching. After the photoresist is removed, the NdFeB magnets, Teflon layers, and a Si spacer are bonded to the spring steel. Finally, a lead zirconate titanate (PZT) cantilever beam with a single NdFeB magnet on one end is bonded to the Si spacer. A photograph of an energy harvesting apparatus corresponding to the embodiment of FIGS. 18 and 19 is shown in FIG. 20.

FIG. 21 shows the output from the energy harvesting apparatus according to FIGS. 18-20 conducted on a shaker table with a 10 Hz input frequency. Due to the physical dimensions of the magnets, only 2-3 pass beneath the piezoelectric beam in a given cycle in this example. FIG. 21 shows voltage as a function of time. After frequency rectification by the magnet arrangement, the rectified frequency is increased to 22 Hz from the 10 Hz input. The voltage output is 12 volts for the central magnet and 8 volts for the side magnets. Based on this result, it is possible to further increase the rectification number by decreasing the size of the arrangement. Based on hard disk drives research, it is possible to create hard ferromagnetic regions as small as 1 μm. This would potentially provide a rectification order of 1000's.

The specific embodiments described above show magnet arrays that have discrete magnets. However, the current invention is not limited to only those particular examples. For example in other embodiments of the current invention, a substantially continuous layer of magnetic material could have a pattern of magnetic polarities that vary in orientation across the surface somewhat similar to how magnetic polarities vary across the surface of a magnetic recording medium, such as a computer hard drive.

The invention has been described in detail with respect to various embodiments, and it will now be apparent from the foregoing to those skilled in the art that changes and modifications may be made without departing from the invention in its broader aspects, and the invention, therefore, as defined in the claims is intended to cover all such changes and modifications as fall within the true spirit of the invention.

We claim:

1. An energy harvesting apparatus, comprising:
an inverse frequency rectifier structured to receive mechanical energy at a first frequency; and
a solid state electromechanical transducer coupled to said inverse frequency rectifier to receive a force provided by said inverse frequency rectifier,
wherein said force when provided by said inverse frequency rectifier causes said solid state transducer to be subjected to a second frequency that is higher than said first frequency to thereby generate electrical power, and
wherein said coupling of said solid state electromechanical transducer to said inverse frequency rectifier is a non-contact coupling.

2. The apparatus according to claim 1, wherein said coupling of said solid state electromechanical transducer to said inverse frequency rectifier is by at least one of magnetic, Coulomb and Van der Waals forces.

3. The apparatus according to claim 1, wherein said solid state electromechanical transducer comprises a piezoelectric material.

4. The apparatus according to claim 3, wherein said solid state electromechanical transducer comprises a magnet attached to said piezoelectric material.

5. The apparatus according to claim 1, wherein said inverse frequency rectifier comprises an array of magnets.

6. The apparatus according to claim 4, wherein said inverse frequency rectifier comprises an array of magnets.

7. The apparatus according to claim 5, wherein said array of magnets alternates in polarity.

8. The apparatus according to claim 6, wherein said array of magnets alternates in polarity.

9. The apparatus according to claim 1, wherein said energy harvesting apparatus is a micro electromechanical system.

10. The apparatus according to claim 1, wherein said solid state electromechanical transducer comprises at least one of an electrostrictive, a magnetostrictive, a ferroelectric and a ferromagnetic material.

11. The apparatus according to claim 1, further comprising:
an electrical storage device coupled to receive said electrical power.

12. The apparatus according to claim 11, wherein said electrical storage device comprises a battery.

13. The apparatus according to claim 11, wherein said electrical storage device comprises a capacitor.

14. An electrical system, comprising:
an energy harvesting apparatus, comprising:
an inverse frequency rectifier structured to receive mechanical energy at a first frequency; and
a solid state electromechanical transducer coupled to said inverse frequency rectifier to receive a force provided by said inverse frequency rectifier,
wherein said force when provided by said inverse frequency rectifier causes said solid state transducer to be subjected to a second frequency that is higher than said first frequency to thereby generate electrical power, and
wherein said coupling of said solid state electromechanical transducer to said inverse frequency rectifier is a non-contact coupling; and
an electrical device coupled to receive said electrical power generated by said energy harvesting apparatus.

15. The system according to claim 14, wherein said electrical device comprises a sensor.

16. The system according to claim 14, wherein said electrical device comprises a communication device.

17. A method of harvesting electrical energy from an environment, comprising:
providing a mechanical structure adapted to be excited into a periodic motion at a first frequency upon being exposed to said environment; and
non-contact coupling said mechanical structure to a solid state component to cause said solid state component to be excited into a periodic motion by a second frequency that is higher than said first frequency,
wherein said solid state component is suitable to generate electrical power at said second frequency when excited through said non-contact coupling to said mechanical structure.

18. The method according to claim 17, further comprising:
storing electrical energy produced by said solid state component.

19. The method according to claim 17, further comprising:
powering an electrical device with electrical energy produced by said solid state component.

20. A method of producing an energy harvesting apparatus, comprising:
forming a frame;
forming a glider that is in vibrational attachment to said frame, said glider comprising an array of magnets; and
forming a magnetic probe attached to said frame and arranged proximate said glider such that said glider and said magnetic probe have a space reserved therebetween,
wherein said glider and said magnetic probe remain free of contact with each other while said energy harvesting apparatus is in operation.
